(19) United States
(12) Patent Application Publication
(10) Pub. No.: US 2016/0033832 A1
(43) Pub. Date: Feb. 4, 2016

(54) TFT-LCD ARRAY SUBSTRATE AND MANUFACTURING METHOD THEREOF

(71) Applicant: Shenzhen China Star Optoelectronics Technology Co. Ltd., Shenzhen, Guangdong (CN)

(72) Inventor: Xiangyang XU, Shenzhen, Guangdong (CN)

(73) Assignee: Shenzhen China Star Optoelectronics Technology Co. Ltd., Shenzhen, Guangdong (CN)

(21) Appl. No.: 14/382,331

(22) PCT Filed: Aug. 6, 2014
(86) PCT No.: PCT/CN2014/083773

§ 371 Date: Sep. 1, 2014

(30) Foreign Application Priority Data
Aug. 4, 2014 (CN) 2014103804673

(51) Int. Cl. G02F 1/1362; G02F 1/1368; H01L 27/12

(52) U.S. Cl. CPC G02F 1/136213; H01L 27/124; H01L 27/1255; H01L 27/1259; H01L 27/1248; H01L 27/1218; G02F 1/1368; G02F 1/136286

(57) ABSTRACT

The present invention provides a TFT-LCD array substrate and a manufacturing method thereof, which comprises a gate line and a data line, wherein a pixel electrode and a thin film transistor are formed in a pixel region defined by the gate line and the data line, a first connecting electrode is further set in the pixel region, connected to the gate line through a first contact hole, and connected to the data line as well. By those mentioned above, the distance between the two electrodes of the storage capacitor is reduced such that the storage capacitance per unit area is increased in the present invention.

### FIELD OF THE INVENTION

The present invention relates to a technique field of liquid crystal display, and more particularly to a TFT-LCD array substrate and manufacturing method thereof.

### BACKGROUND OF THE INVENTION

An image display panel displays by sequentially scanning an aligned M×N matrix line by line, which includes an array substrate for controlling light emitting sources. Take the Thin Film Transistor Liquid Crystal Display (TFT-LCD) as an example, the driver of the array substrate mainly includes a gate driver, i.e. a scan driver, and a data driver, wherein the input clock signal is converted by the gate driver through shift registers and then applied to the gate lines in the liquid crystal display.

There are several techniques for optimizing and reducing the amount of TFT nowadays, but at least one capacitor is necessary because the capacitor is a basic element of the shift register. The capacitance of the capacitor is at least from several pico-farad to a few tens pico-farad, and usually occupies an area from 1000 μm² to 1000000 μm². Usually, an electrode of the capacitor is taken as a gate layer of a TFT, and another electrode is made from the source/drain layer of the TFT while manufacturing the shift register of the gate driver of the TFT-LCD.

The structure of the pixel unit on the TFT-LCD array substrate comprises: a TFT switch, a storage capacitor and a liquid capacitor. Usually, the storage capacitor is constructed by the overlapping area between the Com electrode formed by a first layer metal and the pixel electrode ITO. Because the Com electrode is constructed by metal material and is opaque, a region of the storage capacitor is an opaque region such that the aperture ratio of a pixel region is reverse-proportional to the storage capacitor. FIG. 1 is a schematic diagram of the TFT-LCD array substrate in conventional techniques, wherein the dielectric material of the storage capacitor formed in the overlapping area between the Com metal layer 102 and ITO layer 105 on the glass substrate 101 is the two insulating layers of G—SiNx layer 103 and P—SiNx layer 104, such that the distance is increased and therefore reduces the storage capacitance per unit area in the conventional TFT-LCD array substrate.

### SUMMARY OF THE INVENTION

The technique problem solved by the present invention is to provide a TFT-LCD array substrate and manufacturing method thereof such that the distance between the electrodes of the storage capacitor is reduced and therefore the storage capacitance per unit area is increased.

In order to solve the above mentioned technique problem, the present invention provides a manufacturing method of TFT-LCD array substrate, which comprises forming a gate line and a first insulating layer including a first contact hole on a glass substrate sequentially; setting a first connecting electrode, a source electrode, a drain electrode and a data line, wherein the first connecting electrode is connected to the gate line through the first contact hole and is connected to the data line as well; setting a second insulating layer and a pixel electrode sequentially; wherein the first contact hole is formed above the gate line and through the first insulating layer in order to expose the gate line, and a depth of the second insulating layer is less than the depth of the first insulating layer.

Wherein, a storage capacitor is formed in an overlapping region where the pixel electrode overlaps with the gate line, wherein the second insulating layer is a medium layer of the storage capacitor.

In order to solve the above mentioned technique problem, the present invention provides a TFT-LCD array substrate which comprises a gate line and a data line, wherein a pixel electrode and a thin film transistor are formed in a pixel region defined by the gate line and the data line, a first connecting electrode is set in the pixel region, connected to the gate line through a first contact hole, and connected to the data line as well.

Wherein, a first insulating layer is set on the gate line, and the gate line is exposed from the first insulating layer through the first contact hole.

Wherein, the first connecting electrode is set on the gate line through the first contact hole.

Wherein, a second insulating layer is set on the first connecting electrode, and a depth of the second insulating layer is less than the depth of the first insulating layer.

Wherein, the pixel electrode is set on the second insulating layer, and a storage capacitor is formed in an overlapping region where the pixel electrode overlaps with the gate line, wherein the second insulating layer is a medium layer of the storage capacitor, and a capacitance of the storage capacitor is: C=ε·S/4λkd; wherein S is an area of the overlapping region, d is the depth of the second insulating layer, ε is a dielectric constant of the second insulating layer, and k is the electrostatic constant.

Wherein, the depth of the second insulating layer is 1000˜2500 Å.

In order to solve the above mentioned technique problem, the present invention further provides a manufacturing method of TFT-LCD array substrate, which comprises forming a gate line and a first insulating layer including a first contact hole on a glass substrate sequentially; setting a first connecting electrode, a source electrode, a drain electrode and a data line, wherein the first connecting electrode is connected to the gate line through the first contact hole and is connected to the data line as well; and setting a second insulating layer and a pixel electrode sequentially.

Wherein, the first contact hole is formed above the gate line and exposing the gate line from the first insulating layer through the first contact hole.

Wherein, a depth of the second insulating layer is less than the depth of the first insulating layer.

Wherein, a storage capacitor is formed in an overlapping region where the pixel electrode overlaps with the gate line, wherein the second insulating layer is a medium layer of the storage capacitor.

By the above mentioned technical solution, the beneficial effect of the present invention is: by comprising gate line and data line in the TFT-LCD array substrate, forming a pixel electrode and a thin film transistor in a pixel region defined by the gate line and the data line, setting a first connecting electrode in the pixel region, connecting the first connecting electrode to the gate line through a first contact hole, and connecting the first connecting electrode to the data line as well, the distance between the two electrodes of the storage capacitor is reduced such that the storage capacitance per unit area is increased.

### BRIEF DESCRIPTION OF THE DRAWINGS

FIG. 1 is a schematic diagram of the structure of the conventional TFT-LCD array substrate.

FIG. 2 is a schematic diagram of the plane structure of the TFT-LCD array substrate according to the first embodiment of the present invention.

FIG. 3 is the cross-sectional view in the A1-A1 direction in FIG. 2.

FIG. 4 is a flow chart of the manufacturing method of the TFT-LCD array substrate according to the first embodiment of the present invention.

### DETAILED DESCRIPTION OF PREFERRED EMBODIMENTS

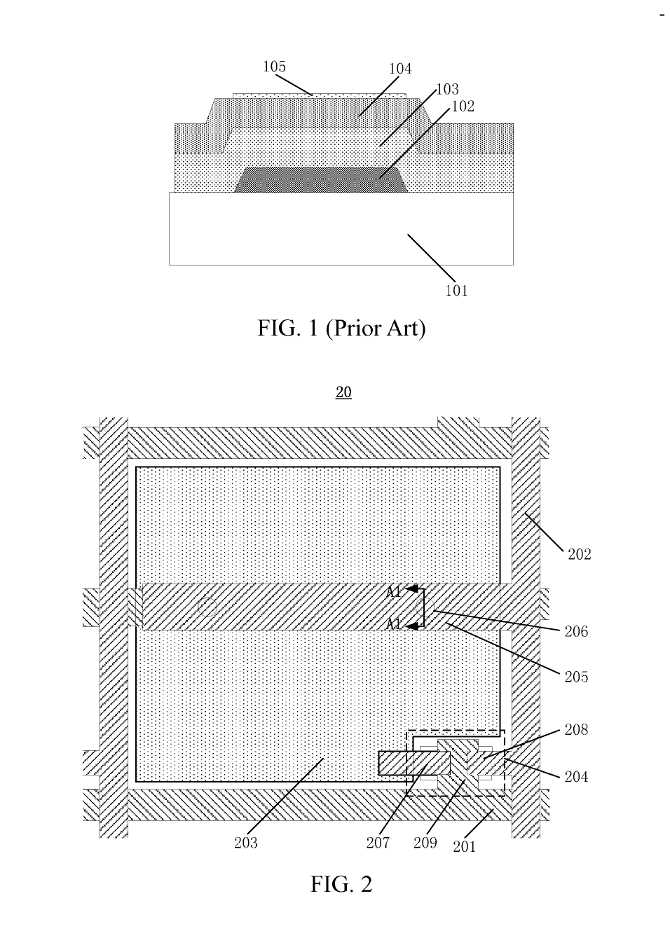

Please refer to FIG. 2, which is a schematic diagram of the plane structure of the TFT-LCD array substrate according to the first embodiment of the present invention. As shown in FIG. 2, the TFT-LCD array substrate 20 comprises a gate line 201 and a data line 202. A pixel electrode 203 and a thin film transistor 204 are formed in a pixel region defined by the gate line 201 and the data line 202. A first connecting electrode 205 is further set in the pixel region. The first connecting electrode 205 is connected to the gate line 201 through a first contact hole 206, and is connected to the data line 202 as well, i.e. the first connect electrode is a source/drain line. The thin film transistor 204 comprises a source 207, a drain 208 and a gate 209. The first connecting electrode 205, the data line 202, the source 207 and the drain 208 is formed in the same pattern process.

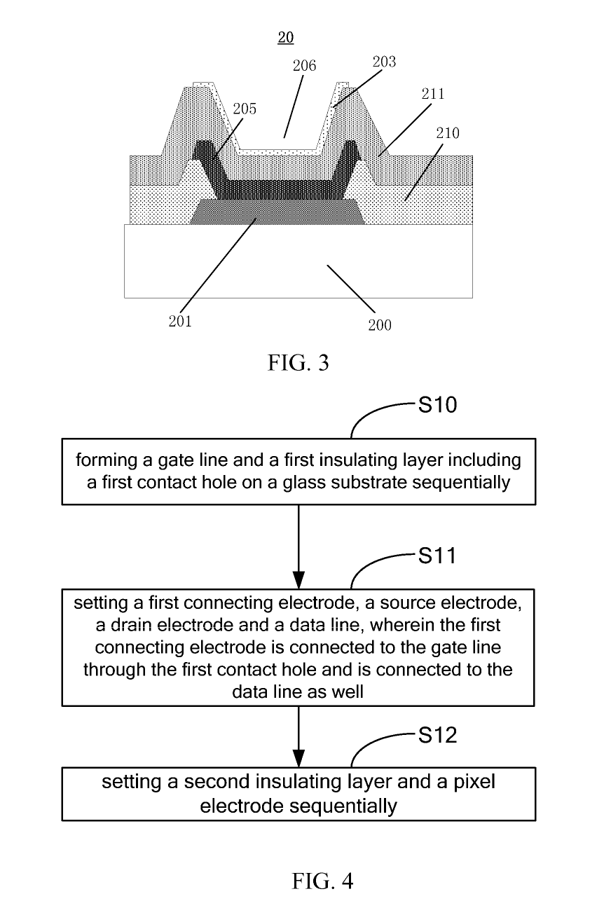

FIG. 3 is the cross-sectional view in the A1-A1 direction in FIG. 2. As shown in FIG. 3, a first insulating layer 210 is set on the gate line 201, and the gate line 201 is exposed from the first insulating layer 210 through the first contact hole 206. The first connecting electrode 205 is set on the gate line 201 through the first contact hole 206. Wherein, the gate line 201 is set on the glass substrate 200. A second insulating layer 211 is set on the first connecting electrode 205. The pixel electrode 203 is set on the second insulating layer 211, and a storage capacitor is formed in an overlapping region where the pixel electrode 203 overlaps with the gate line 201, wherein the second insulating layer 211 is a medium layer of the storage capacitor. A capacitance of the storage capacitor is: C=ε·S/4πkd; wherein S is an area of the overlapping region where the pixel electrode 203 overlaps with the gate line 201, d is the depth of the second insulating layer 211, ε is a dielectric constant of the second insulating layer 211, and k is the electrostatic constant. In the embodiment, the first insulating layer 210 is better a G—SiNx layer, and the depth thereof is better about 4000˜5000 Å, while the second insulating layer 211 is better a P—SiNx layer, and the depth thereof is better about 1000˜2500 Å. That is, the depth of the second insulating layer 211 is less than the depth of the first insulating layer 210. The embodiment reduces the distance between the two electrodes of the storage capacitor to the depth of the second insulating layer 211 such that the storage capacitance per unit area is increased as the distance being reduced. The TFT-LCD array substrate is adapted to the liquid crystal display mode of the TN type, the VA type and the IPS type.

Please refer to FIG. 4. FIG. 4 is a flow chart of the manufacturing method of the TFT-LCD array substrate according to the first embodiment of the present invention. As shown in FIG. 4, the manufacturing method of TFT-LCD array substrate comprises:

Step S10: forming a gate line and a first insulating layer including a first contact hole on a glass substrate sequentially.

Wherein, the first contact hole is formed above the gate line, and the gate line is exposed from the first insulating layer through the first contact hole.

Step S11: setting a first connecting electrode, a source electrode, a drain electrode and a data line, wherein the first connecting electrode is connected to the gate line through the first contact hole and is connected to the data line as well.

Wherein, the first connecting electrode is the S/D line.

Step S12: setting a second insulating layer and a pixel electrode sequentially.

Wherein, the pixel electrode covers on the second insulating layer. The first insulating layer is better a G—SiNx layer, and the depth thereof is better about 4000˜5000 Å. The second insulating layer is better a P—SiNx layer, and the depth thereof is better about 1000˜2500 Å. That is, the depth of the second insulating layer is less than the depth of the first insulating layer. A storage capacitor is formed in an overlapping region where the pixel electrode overlaps with the gate line, wherein the second insulating layer is a medium layer of the storage capacitor. A capacitance of the storage capacitor is: C=ε·S/4πkd; wherein S is an area of the overlapping region where the pixel electrode overlaps with the gate line, d is the depth of the second insulating layer, ε is a dielectric constant of the second insulating layer, and k is the electrostatic constant. Accordingly, the distance between the two electrodes of the storage capacitor is reduced to the depth of the second insulating layer such that the storage capacitance per unit area is increased.

In summary, by comprising gate line and data line in the TFT-LCD array substrate, forming a pixel electrode and a thin film transistor in a pixel region defined by the gate line and the data line, setting a first connecting electrode in the pixel region, connecting the first connecting electrode to the gate line through a first contact hole, and connecting the first connecting electrode to the data line as well in the present invention, the distance between the two electrodes of the storage capacitor is reduced such that the storage capacitance per unit area is increased.

The description made above is just the embodiments of the present invention but not limitations to the claim scope of the present invention. Those equivalent structures or equivalent procedure variations made according to the contents of the specification and the drawings of the present invention, or directly or indirectly used in other related technique field, are included in the patent protection scope of the present invention as well.

What is claimed is:

1. A manufacturing method of TFT-LCD array substrate, which is characterized in comprising:
forming a gate line and a first insulating layer including a first contact hole on a glass substrate sequentially;
setting a first connecting electrode, a source electrode, a drain electrode and a data line, wherein the first connecting electrode is connected to the gate line through the first contact hole and is connected to the data line as well; and
setting a second insulating layer and a pixel electrode sequentially;
wherein the first contact hole is formed above the gate line and through the first insulating layer in order to expose the gate line, and a depth of the second insulating layer is less than the depth of the first insulating layer.

2. The manufacturing method according to claim 1, which is characterized in forming a storage capacitor in an overlapping region where the pixel electrode overlaps with the gate line, wherein the second insulating layer is a medium layer of the storage capacitor.

3. A TFT-LCD array substrate, which is characterized in comprising a gate line and a data line, wherein a pixel electrode and a thin film transistor are formed in a pixel region defined by the gate line and the data line, a first connecting electrode is set in the pixel region, connected to the gate line through a first contact hole, and connected to the data line as well.

4. The TFT-LCD array substrate according to claim 3, which is characterized in that a first insulating layer is set on the gate line, and the gate line is exposed from the first insulating layer through the first contact hole.

5. The TFT-LCD array substrate according to claim 4, which is characterized in that the first connecting electrode is set on the gate line through the first contact hole.

6. The TFT-LCD array substrate according to claim 5, which is characterized in that a second insulating layer is set on the first connecting electrode, and a depth of the second insulating layer is less than the depth of the first insulating layer.

7. The TFT-LCD array substrate according to claim 6, which is characterized in that the pixel electrode is set on the second insulating layer, and a storage capacitor is formed in an overlapping region where the pixel electrode overlaps with the gate line, wherein the second insulating layer is a medium layer of the storage capacitor, and a capacitance of the storage capacitor is:
C=εS/4πkd;
wherein S is an area of the overlapping region, d is the depth of the second insulating layer, ε is a dielectric constant of the second insulating layer, and k is the electrostatic constant.

8. The TFT-LCD array substrate according to claim 7, which is characterized in that the depth of the second insulating layer is 1000˜2500 Å.

9. A manufacturing method of TFT-LCD array substrate, which is characterized in comprising:
forming a gate line and a first insulating layer including a first contact hole on a glass substrate sequentially;
setting a first connecting electrode, a source electrode, a drain electrode and a data line, wherein the first connecting electrode is connected to the gate line through the first contact hole and is connected to the data line as well; and
setting a second insulating layer and a pixel electrode sequentially.

10. The manufacturing method according to claim 9, which is characterized in forming the first contact hole above the gate line and exposing the gate line from the first insulating layer through the first contact hole.

11. The manufacturing method according to claim 9, which is characterized in that a depth of the second insulating layer is less than the depth of the first insulating layer.

12. The manufacturing method according to claim 10, which is characterized in forming a storage capacitor in an overlapping region where the pixel electrode overlaps with the gate line, wherein the second insulating layer is a medium layer of the storage capacitor.
